(19) United States
(12) Patent Application Publication
(10) Pub. No.: US 2003/0034559 A1
(43) Pub. Date: Feb. 20, 2003

(54) Ball grid array package with electrically-conductive bridge

(75) Inventor: Chih Chin Liao, Chang Hua (TW)

Correspondence Address: EDWARDS & ANGELL, LLP, 101 FEDERAL STREET, BOSTON, MA, 02110, US

(73) Assignee: Siliconware Precision Industries Co., Ltd., Taichung (TW)

(21) Appl. No.: 09/929,765

(22) Filed: Aug. 14, 2001

(51) Int. Cl. H01L 23/48

(52) U.S. Cl. 257/738

(57) ABSTRACT

A method for electrically connecting a semiconductor chip to solder balls on a BGA (Ball Grid Array) package is proposed. The proposed method is characterized by the use of an electrically-conductive bridge to span in an overhead manner across a continuous electrically-conductive trace that is interposed between a corresponding pair of bond finger and via. The electrically-conductive bridge can be either a gold wire bonded through existing wire-bonding process, or a zero-resistance chip resistor bonded through existing surface-mount technology (SMT). Conventionally, the interposing trace can be bypassed by using a multi-layer substrate. By the proposed method, however, it can be implemented on existing single-layer substrate without having to use multi-layer substrate, and which can be implemented by using existing technology, such as wire-bonding technology or surface-mounting technology, without having to employ more expensive and advanced technologies.

### BACKGROUND OF THE INVENTION

1. Field of the Invention

This invention relates to semiconductor packaging technology, and more particularly, to a method of electrically connecting a semiconductor chip to an array of solder balls on a BGA (Ball Grid Array) package.

2. Description of Related Art

BGA (Ball Grid Array) is an advanced type of semiconductor packaging technology which is based on a substrate as chip carrier whose front side is used for mounting one or more semiconductor chips and whose back side is implanted with a grid array of solder balls. During SMT (Surface Mount Technology) process, the BGA package can be mechanically bonded and electrically coupled to an external printed circuit board (PCB) by means of these solder balls.

FIG. 1 is a schematic diagram illustrated in sectional view of the basic architecture of a typical BGA package. As shown, this BGA package includes: (a) a substrate 10 having a front side 10a and a back side 10b; (b) a semiconductor chip 20 mounted on the front side 10a of the substrate 10, and which includes an array of bond pads 30 on the upper side thereof; and (c) an array of solder balls 40 implanted on the back side 10b of the substrate 10. By the BGA technology, the bond pads 30 on the semiconductor chip 20 are each electrically connected in a one-to-one correspondence to one of the solder balls 30 over a signal transmission path consisting of a bonding wire 50, an electrically-conductive bond finger 60, an electrically-conductive trace 70, and an electrically-conductive via 80 (note that FIG. 1 and all the other drawings are simplified schematic diagrams showing only those components that are related to the invention for demonstrative purpose, and which are not drawn to actual shapes, sizes, and scales which are an arbitrary design choice in practical applications; the practical layout on the BGA package may be much more complex).

FIG. 2 is a schematic diagram illustrated in top view of an example of the trace layout scheme on the BGA package. As shown, the trace layout scheme here is used to electrically connect a plurality of bond pads (only four are shown in FIG. 2 designated by the reference numerals 30A, 30B, 30C, 30D) to a corresponding array of solder balls (only four are shown here in dotted circles and designated by the reference numerals 40A, 40B, 40C, 40D). By conventional method, a corresponding number of bond fingers 60A, 60B, 60C, 60D are provided beside the semiconductor chip 20 for the semiconductor chip 20 to be electrically connected thereto by means of bonding wires 50A, 50B, 50C, 50D respectively. Further, a plurality of vias 80A, 80B, 80C, 80D are electrically connected to the solder balls 40A, 40B, 40C, 40D respectively.

In the case of FIG. 2, all the bond fingers 60A, 60B, 60C, 60D can be connected to their corresponding vias 80A, 80B, 80C, 80D by providing continuous electrically-conductive traces 70A, 70B, 70C, 70D, without the problem of trace interposition.

FIG. 3 shows an example of trace interposition in the circuit layout design on the BGA package. As shown, assume the bond finger 60A is to be connected to the solder ball 40B while the bond finger 60B is to be connected to the solder ball 40A. In this case, the bond finger 60A still can be connected to its corresponding via 80B by means of a continuous electrically-conductive trace 70A; however, it can be seen from FIG. 3 that this trace 70A is interposed between the corresponding pair of bond linger 60B and via 80A. Therefore, it would be impossible to use a continuous electrically-conductive trace to connect the bond finger 60B to the via 80A.

FIG. 4 shows a conventional solution to the foregoing problem of trace interposition shown in FIG. 3. As shown, this solution is based on a multi-layer substrate 1′ having an upper layer 11′ and a bottom layer 12′ to provide an upper-layer trace 71, an upper-layer via 72, a bottom-layer trace 73, and a bottom-layer via 74, which are routed in a suitable manner that can bypass the interposing electrically-conductive traces 70A and thereby connect the bond finger 60B to its corresponding solder ball 40A.

In a BGA package with a great number of solder balls and bond pads, the trace layout scheme would become more complex such that the multi-layer substrate may need more layers, up to six or more, to connect those bond fingers and solder balls that are interposed by other traces. One drawback to the use of multi-layer substrate, however, is that it would significantly increase the complexity of layout design as well as material cost, making the overall packaging process quite cost-ineffective.

Other solutions to the problem of trace interposition include the use of fine pitch traces, laser vias, Gold Pattern Plating (GPP), via on pad, to name a few. One drawback to these solutions, however, is that they are quite costly to employ.

Related patents, include, for example, the following U.S. Pat. Nos.:

U.S. Pat. No. 5,545,923 “SEMICONDUCTOR DEVICE ASSEMBLY WITH MINIMIZED BOND FINGER CONNECTIONS”;

U.S. Pat. No. 5,650,660 “CIRCUIT PATTERN FOR A BALL GRID ARRAY INTEGRATED CIRCUIT PACKAGE”;

U.S. Pat. No. 5,641,988 “MULTI-LAYERED INTEGRATED CIRCUIT PACKAGE HAVING REDUCED PARASITIC NOISE CHARACTERISTICS”;

U.S. Pat. No. 6,008,534 “INTEGRATED CIRCUIT PACKAGE HAVING SIGNAL TRACES INTERPOSED BETWEEN POWER AND GROUND CONDUCTORS IN ORDER TO FORM STRIPLINE TRANSMISSION LINES”.

None of these patents, however, teach solutions to the above-mentioned problem of trace interposition.

### SUMMARY OF THE INVENTION

It is therefore an objective of this invention to provide a method of electrically connecting semiconductor chip to solder balls on BGA package, which can be implemented on a single-layer substrate rather than a multi-layer substrate, so as to make the trace layout design easier and more cost-effective to implement than the prior art.

It is another objective of this invention to provide a method of electrically connecting semiconductor chip to solder balls on BGA package, which can be implemented without having to employ highly expensive technology.

The method according to the invention is characterized by the use of an electrically-conductive bridge to span in an overhead manner across a continuous electrically-conductive trace that is interposed between a corresponding pair of bond finger and via. The electrically-conductive bridge can be either a gold wire bonded through existing wire-bonding process, or a zero-resistance chip resistor bonded through existing surface-mount technology (SMT). Conventionally, the interposing trace can be bypassed by using a multi-layer substrate. By the proposed method, however, it can be implemented on existing single-layer substrate without having to use multi-layer substrate, and which can be implemented by using existing technology, such as wire-bonding technology or surface-mounting technology, without having to employ more expensive and advanced technologies.

### BRIEF DESCRIPTION OF DRAWINGS

The invention can be more fully understood by reading the following detailed description of the preferred embodiments, with reference made to the accompanying drawings, wherein:

FIG. 1 (PRIOR ART) is a schematic sectional diagram showing the basic architecture of a typical BGA package;

FIG. 2 (PRIOR ART) is a schematic diagram showing an example of the circuit layout on the front side of the BGA package in the case of no trace interposition;

FIG. 3 (PRIOR ART) is a schematic diagram showing an example of the circuit layout on the front side of the BGA package in the case of trace interposition;

FIG. 4 (PRIOR ART) is a schematic sectional diagram showing the use of a multi-layer substrate for the implementation of the circuit layout scheme shown in FIG. 3;

FIG. 5 is a schematic diagram used to depict the basic concept of the circuit layout method according to the invention to solve the problem of trace interposition;

FIG. 6 is a schematic sectional diagram showing a first preferred embodiment of the circuit layout method according to the invention; and

FIG. 7 is a schematic sectional diagram showing a second preferred embodiment of the circuit layout method according to the invention.

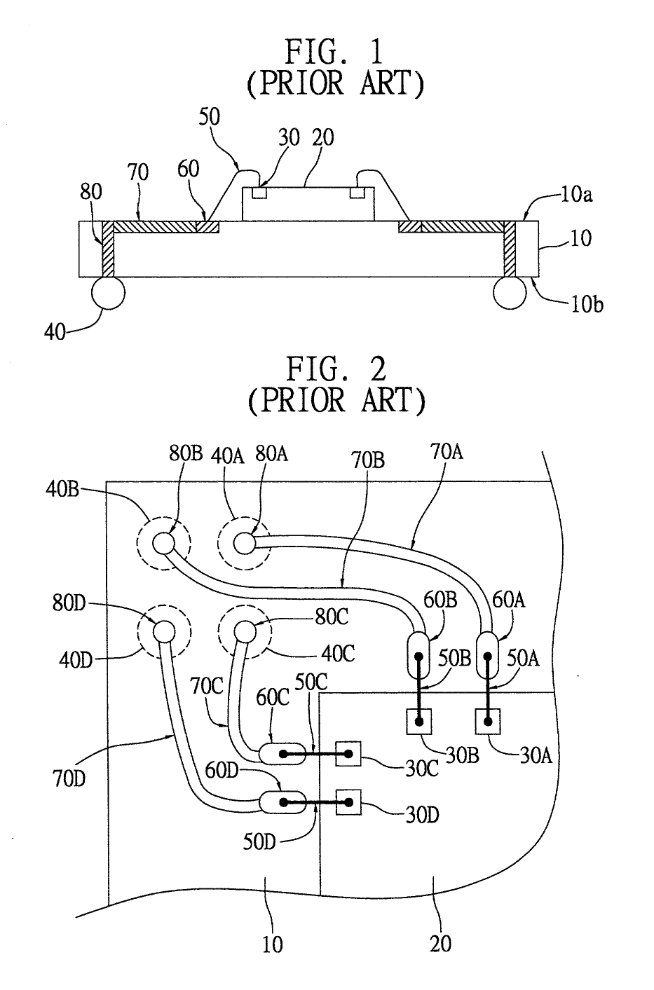

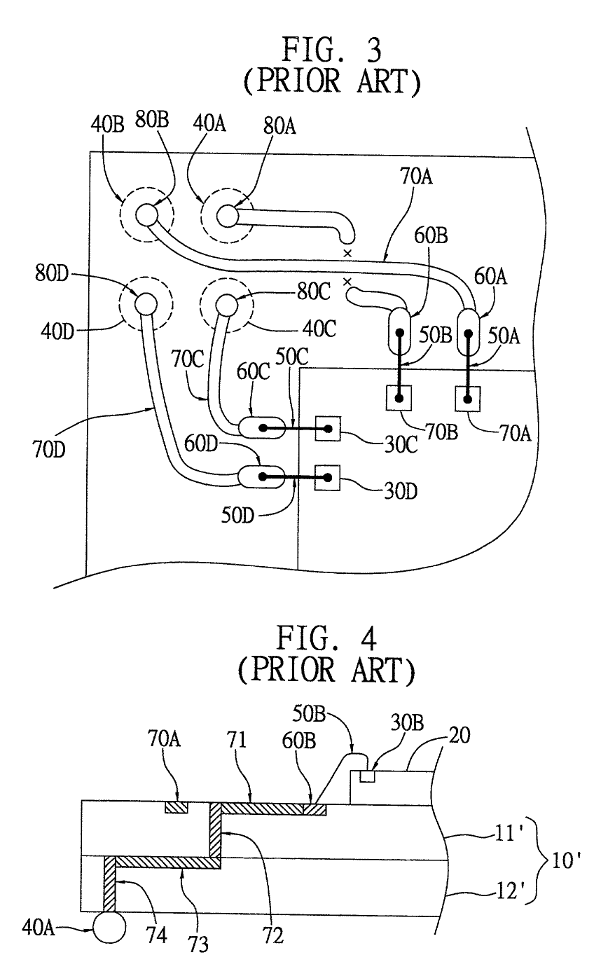

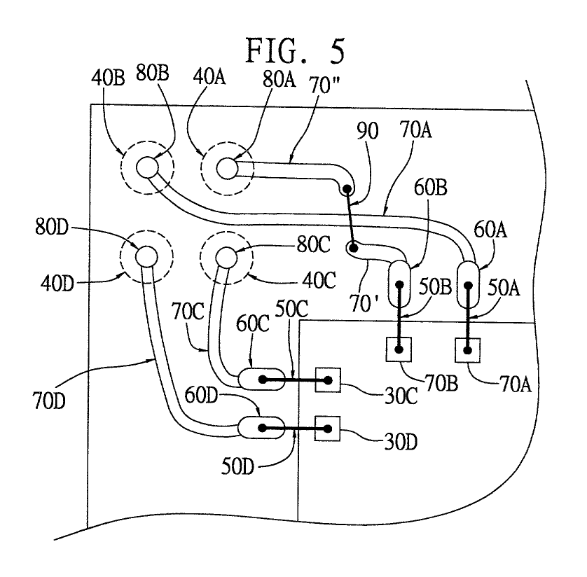

### DETAILED DESCRIPTION OF PREFERRED EMBODIMENTS

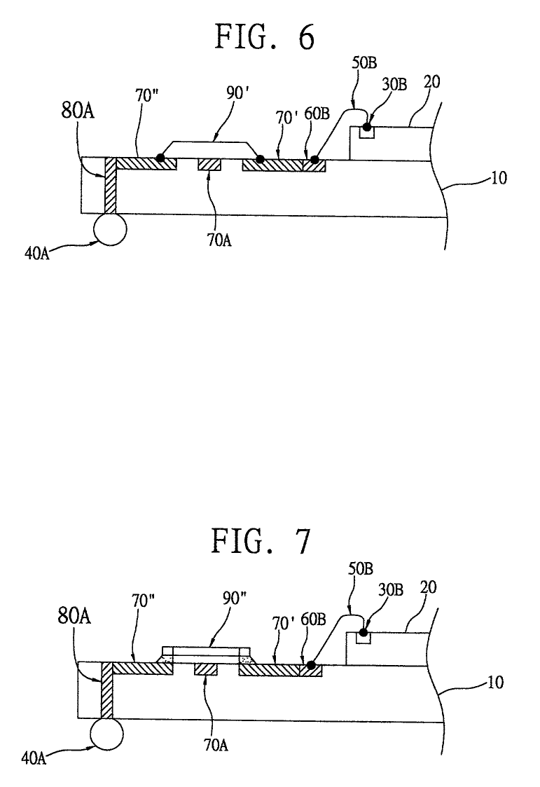

The method according to the invention for electrically connecting a semiconductor chip to solder balls on a BGA package is disclosed in full details by way of preferred embodiments in the following with reference to FIG. 5, FIG. 6, and FIG. 7.

Referring to FIG. 5, the invention is here utilized on a BGA package having a substrate 10 and a semiconductor chip 20 for the purpose of electrically connecting the bond pads (only four are shown and designated by the reference numerals 30A, 30B, 30C, 30D) on the semiconductor chip 20 to the corresponding solder balls (only four are shown and designated by the reference numerals 40A, 40B, 40C, 40D) on the back side 10b of the substrate 10.

To electrically connect the bond pads 30A, 30B, 30C, 30D to the solder balls 40A, 40B, 40C, 40D, a corresponding number of bond fingers 60A, 60B, 60C, 60D are provided beside the semiconductor chip 20; and further, a plurality of vias 80A, 80B, 80C, 80D are formed in such a manner as to penetrate through the substrate 10, and which are electrically connected to the corresponding solder balls 40A, 40B, 40C, 40D on the back side 10b of the substrate 10.

Assume the bond finger 60A is to be connected to the solder ball 40B while the bond finger 60B is to be connected to the solder ball via 40A; and farther assume that the bond finger 60A is already connected to the corresponding via 80B by means of a continuous electrically-conductive trace 70A which is interposed between the corresponding pair of bond finger 60B and via 80A. Therefore, it would be impossible to form a continuous electrically-conductive trace to connect the bond finger 60B to the via 80A.

The invention solves the foregoing problem of trace interposition by providing an electrically-conductive bridge 90 to span in an overhead manner across the interposing electrically-conductive trace 70A, and then electrically connecting one end of the electrically-conductive bridge 90 by means of a first trace 70′ to the bond finger 60B and the other end of the same by means of a second trace 70″ to the via 80A (note that if the first end of the electrically-conductive bridge 90 is directly bonded to the bond finger 60B, the first trace 70′ can be eliminated; and if the second end of the electrically-conductive bridge 90 is directly bonded to the via 80A, the second trace 82 can be eliminated).

The foregoing electrically-conductive bridge 90 can be realized in various different ways, as the following two examples respectively shown in FIG. 6 and FIG. 7.

As shown in FIG. 6, the electrically-conductive bridge 90 shown in FIG. 5 can be realized by bonding a wire, such as a gold wire 90′ between the terminal of the first trace 70′ and the terminal of the second trace 70″. This can be implemented by using existing wire-bonding process.

As shown in FIG. 7, the electrically-conductive bridge 90 shown in FIG. 5 can be realized by bonding a zero-resistance chip resistor 90″ between the terminal of the first trace 70′ and the terminal of the second trace 70″. This can be implemented by using existing surface-mounting technology (SMT).

In conclusion, the invention provides a new method for electrically connecting semiconductor chip to solder balls on a BGA package, which can be implemented by using existing single-layer substrate without having to use complex and expensive multi-layer substrate, and which can be implemented by using existing technology, such as wire-bonding technology or SMT technology, without having to employ more expensive and advanced technologies. The invention is therefore more advantageous to use than the prior art.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A method for electrically connecting a semiconductor chip to an array of solder balls on a BGA package; the semiconductor chip having an array of bond pads and being mounted on a substrate;
the method comprising the steps of:
(1) providing a plurality of electrically-conductive bond fingers, each bond finger being electrically connected to the corresponding one of the bond pads on the semiconductor chip;
(2) providing a plurality of electrically conductive vias, each via penetrating through the substrate and electrically connected to one of the solder balls;
(3) providing a plurality of continuous electrically-conductive traces on the substrate for electrically connecting a subgroup of the bond fingers to their corresponding ones of the vias;
(4) if any one of the continuous electrically-conductive traces is interposed between a corresponding pair of bond finger and via, then performing the following substeps of:
(4-1) providing an electrically-conductive bridge to span in an overhead manner across the interposing electrically-conductive trace, and
(4-2) electrically connecting the two ends of the electrically-conductive bridge respectively to the corresponding pair of bond finger and via.

2. The method of claim 1, wherein in said substep (4-1), the electrically-conductive bridge is a bonding wire mounted through wire-bonding technology.

3. The method of claim 2, wherein the bonding wire is a gold wire.

4. The method of claim 1, wherein in said substep (4-1), the electrically-conductive bridge is a chip resistor mounted through SMT technology.

5. The method of claim 4, wherein chip resistor is a zero-resistance chip resistor.

6. A BGA package, which comprises:
(a) a substrate having a front side and a back side;
(b) a semiconductor chip mounted on the front side of the substrate; the semiconductor chip having an array of bond pads;
(c) an array of solder balls implanted on the back side of the substrate;
(d) an array of bond fingers provided beside the semiconductor chip and which are electrically connected to the bond pads on the semiconductor chip;
(e) an array of electrically-conductive vias, each penetrating from the front side to the back side of the substrate and electrically connected to one of the solder balls;
(f) a plurality of continuous electrically-conductive traces for electrically connecting a first subgroup of the bond fingers to corresponding ones of the vias; these continuous electrically-conductive traces including at least one being interposed between a second subgroup of the bond fingers and their corresponding vias; and
(g) an electrically-conductive bridge which spans in an overhead manner across each interposing trace and having one end electrically connected to the corresponding via and the other end electrically connected to the corresponding bond finger.

7. The BGA package of claim 6, wherein the electrically-conductive bridge is a bonding wire mounted through wire-bonding technology.

8. The BGA package of claim 7, wherein the bonding wire is a gold wire.

9. The BGA package of claim 6, wherein the electrically-conductive bridge is a chip resistor mounted through SMT technology.

10. The BGA package of claim 9, wherein chip resistor is a zero-resistance chip resistor.
